(19) United States
(12) Patent Application Publication
(10) Pub. No.: US 2011/0050312 A1
(43) Pub. Date: Mar. 3, 2011

(54) MULTI-PHASE CLOCK GENERATION CIRCUIT

(75) Inventor: Satoshi FUJINO, Kanagawa (JP)

(73) Assignee: NEC Electronics Corporation

(21) Appl. No.: 12/820,756

(22) Filed: Jun. 22, 2010

(30) Foreign Application Priority Data
Aug. 31, 2009 (JP) 2009-199411

(51) Int. Cl. H03K 5/13

(52) U.S. Cl. 327/237

(57) ABSTRACT

A multi-phase clock generation circuit including a phase interpolation circuit that generates and outputs an interpolation signal based on first and second clock signals, the interpolation signal interpolating a phase between output clock signals corresponding to the first and the second clock signals, and a control circuit that generates a first control signal to adjust a phase of the interpolation signal and outputs the first control signal to the phase interpolation circuit, in which the control circuit includes a timing detection circuit that detects a timing of a change in a logic value of the interpolation signal, and a control signal generation circuit that generates the first control signal according to a detection result in the timing detection circuit.

### INCORPORATION BY REFERENCE

This application is based upon and claims the benefit of priority from Japanese patent application No. 2009-199411, filed on Aug. 31, 2009, the disclosure of which is incorporated herein in its entirety by reference.

### BACKGROUND

1. Field of the Invention

The present invention relates to a multi-phase clock generation circuit, and more particularly, to control of phase interpolation.

2. Description of Related Art

A clock control system typically includes a clock signal generation circuit such as a PLL (Phase Locked Loop) circuit, a DLL (Delay Locked Loop) circuit, and a CDR (Clock Data Recovery) circuit. Such a clock signal generation circuit generates stable clock signals with high accuracy. The clock signal generation circuit achieves high-speed synchronous operation using a multi-phase clock signal.

In prior arts, signals output from a plurality of delay circuits that form a ring oscillator have been used as a multi-phase clock signal. The ring oscillator is included in a VCO (Voltage Controlled Oscillator), for example. However, the circuits according to the prior arts cannot deal with the multi-phase clock signal that requires a larger number of phases.

In recent years, a phase interpolation circuit has been used to solve such a problem. For example, a multi-phase clock generation circuit disclosed in each of Japanese Unexamined Patent Application Publication Nos. 2001-273048, 2002-190724, 2003-87113, and 2003-333021 includes an interpolator (phase interpolation circuit) that generates an interpolation signal that interpolates a phase of clock signals having different phases with each other. The interpolator has a function to control the phase of the interpolation signal that varies depending on external environments including a temperature.

### SUMMARY

The circuit described above requires control of the phase of the interpolation signal using a control signal supplied from outside. Hence, according to the related arts, the phase of the interpolation signal cannot be controlled with high accuracy unless the frequencies of the clock signals which are the target of the phase interpolation can be specified. Further, according to the related arts, a circuit for measuring frequencies needs to be provided to measure the frequencies of the clock signals which are the target of the phase interpolation. This increases the size of the circuit. Further, the control signal supplied from outside cannot cancel the influence given on the phase interpolation circuit by a manufacturing process, a power supply voltage and a temperature in a usage environment.

A first exemplary aspect of the present invention is a multi-phase clock generation circuit including a phase interpolation circuit that generates and outputs an interpolation signal based on first and second clock signals, the interpolation signal interpolating a phase between output clock signals corresponding to the first and the second clock signals, and a control circuit that generates a first control signal to adjust a phase of the interpolation signal and outputs the first control signal to the phase interpolation circuit, in which the control circuit includes a timing detection circuit that detects a timing of a change in a logic value of the interpolation signal, and a control signal generation circuit that generates the first control signal according to a detection result in the timing detection circuit.

According to the circuit configuration described above, the phase of the interpolation signal can be automatically controlled with high accuracy.

The present invention provides a multi-phase clock generation circuit that is capable of automatically controlling the phase of the interpolation signal with high accuracy.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 shows a multi-phase clock generation circuit according to a first exemplary embodiment of the present invention;

FIG. 2 shows a control circuit according to the first exemplary embodiment of the present invention;

FIG. 3 shows the control circuit according to the first exemplary embodiment of the present invention;

FIG. 4 shows a multi-phase clock generation circuit according to a second exemplary embodiment of the present invention;

FIG. 5 shows a control circuit according to the second exemplary embodiment of the present invention;

FIG. 6 shows the control circuit according to the second exemplary embodiment of the present invention;

FIG. 7 shows the control circuit according to the second exemplary embodiment of the present invention;

FIG. 8 shows a multi-phase clock generation circuit according to a third exemplary embodiment of the present invention;

FIG. 9 shows a control circuit according to the third exemplary embodiment of the present invention;

FIG. 10 shows the control circuit according to the third exemplary embodiment of the present invention;

FIG. 11 shows a phase interpolation circuit;

FIG. 12 shows a phase interpolation circuit;

FIG. 13 shows a waveform of an interpolation signal output from the phase interpolation circuit;

FIG. 14 shows a waveform of an interpolation signal output from the phase interpolation circuit;

FIG. 15 shows waveforms of input/output signals of the phase interpolation circuit according to the first and second exemplary embodiments of the present invention;

FIG. 16 shows waveforms of input/output signals of a delay information generation circuit according to a third exemplary embodiment of the present invention;

FIG. 17 shows another phase interpolation circuit;

FIG. 18 shows another phase interpolation circuit;

FIG. 19 shows another phase interpolation circuit;

FIG. 20 shows another phase interpolation circuit; and

FIG. 21 shows another phase interpolation circuit.

### DETAILED DESCRIPTION OF THE EXEMPLARY EMBODIMENTS

The first to third exemplary embodiments can be combined as desirable by one of ordinary skill in the art.

Hereinafter, specific exemplary embodiments of the present invention will be described in detail with reference to the drawings. Throughout the drawings, the same components are denoted by the same reference symbols, and overlapping description will be omitted as appropriate for the sake of clarity.

### First Exemplary Embodiment

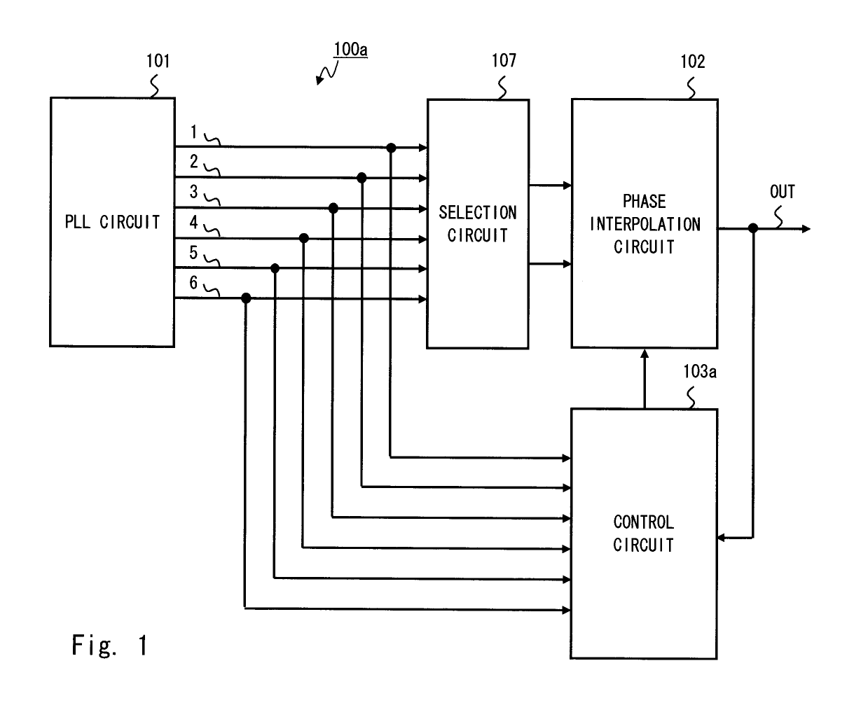

A first exemplary embodiment of the present invention will be described with reference to the drawings. FIG. 1 shows a multi-phase clock generation circuit 100a according to the first exemplary embodiment of the present invention. The multi-phase clock generation circuit 100a includes a PLL circuit (phase locked loop circuit) 101 which generates a plurality of clock signals, a selection circuit 107 which selects two clock signals among the plurality of clock signals, a phase interpolation circuit 102 which generates an interpolation signal based on the two clock signals, and a control circuit 103a which outputs a first control signal to control the phase of the interpolation signal based on the interpolation signal. In the first exemplary embodiment, the first control signal “to control the phase of the interpolation signal” means the first control signal “which controls the phase interpolation circuit 102 so that the phase interpolation circuit 102 generates the interpolation signal having the desired phase”. For example, when the phase between the two output clock signals is interpolated in a ratio of 1 to 1, the control circuit 103a outputs the first control signal so that the phase interpolation circuit generates the interpolation signal accordingly.

Although not shown in the drawings, the multi-phase clock generation circuit 100a includes a plurality of phase interpolation circuits 102. For example, assume that the multi-phase clock generation circuit 100a includes three phase interpolation circuits A, B, and C. At this time, for example, a clock signal 1 is supplied to input terminals INA and INB of the phase interpolation circuit A. The clock signal 1 is supplied to an input terminal INA of the phase interpolation circuit B, and a clock signal 2 is supplied to an input terminal INB. The clock signal 2 is supplied to input terminals INA and INB of the phase interpolation circuit C. Therefore, the phase interpolation circuit A outputs an output clock signal A according to the clock signal 1. The phase interpolation circuit C outputs an output clock signal C according to the clock signal 2. The phase interpolation circuit B outputs an interpolation signal that interpolates the phases of the output clock signals A and C as an output clock signal B. In this way, the multi-phase clock generation circuit 100a generates a multi-phase clock signal including a plurality of output clock signals.

The configuration of the circuit shown in FIG. 1 will be described. Clock signal output terminals of the PLL circuit 101 are connected to the respective input terminals of the selection circuit 107. The clock signal output terminals of the PLL circuit 101 are further connected to the respective clock signal input terminals of the control circuit 103a. Two output terminals of the selection circuit 107 are connected to the respective clock input terminals of the phase interpolation circuit 102. An output terminal of the phase interpolation circuit 102 is connected to an external output terminal OUT of the multi-phase clock generation circuit 100a and an interpolation signal input terminal of the control circuit 103a. A control signal output terminal of the control circuit 103a is connected to a control signal input terminal of the phase interpolation circuit 102. The circuit shown in FIG. 1 is a multi-phase clock generation circuit for detecting a falling edge.

The operation in the circuit shown in FIG. 1 will now be described. The PLL circuit 101 outputs six clock signals 1 to 6 having different phases with each other. The phases of the clock signals 1 to 6 are different by 60 degrees. In this example, the phase of the clock signal 1 is 0 degrees (standard). The phase difference between the clock signal 1 and the clock signal 2 is 60 degrees. The phase difference between the clock signal 1 and the clock signal 3 is 120 degrees. The phase difference between the clock signal 1 and the clock signal 4 is 180 degrees. The phase difference between the clock signal 1 and the clock signal 5 is 240 degrees. The phase difference between the clock signal 1 and the clock signal 6 is 300 degrees. In practice, the number of clock signals output from the PLL circuit 101 is not limited to six. Further, each phase difference between the clock signals is not limited to 60 degrees.

The clock signals 1 to 6 are input to the respective input terminals of the selection circuit 107. The clock signals 1 to 6 are further input to the respective clock signal input terminals of the control circuit 103a. The selection circuit 107 selects two clock signals having the phase difference of 60 degrees among the clock signals 1 to 6, and outputs the selected two clock signals to the phase interpolation circuit 102. The phase interpolation circuit 102 outputs an interpolation signal based on the two clock signals that are supplied. The interpolation signal output from the phase interpolation circuit 102 is supplied to the external output terminal OUT of the multi-phase clock generation circuit 100a. Further, this interpolation signal is supplied to the interpolation signal input terminal of the control circuit 103a.

The control circuit 103a detects a timing of a change in a logic value of the interpolation signal output from the phase interpolation circuit 102. The control circuit 103a then outputs the first control signal to control the phase of the interpolation signal to the phase interpolation circuit 102.

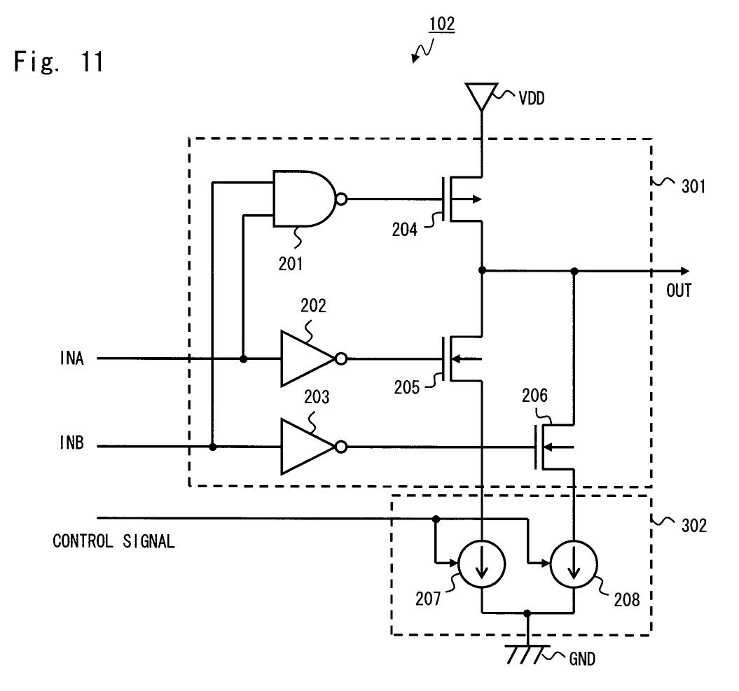

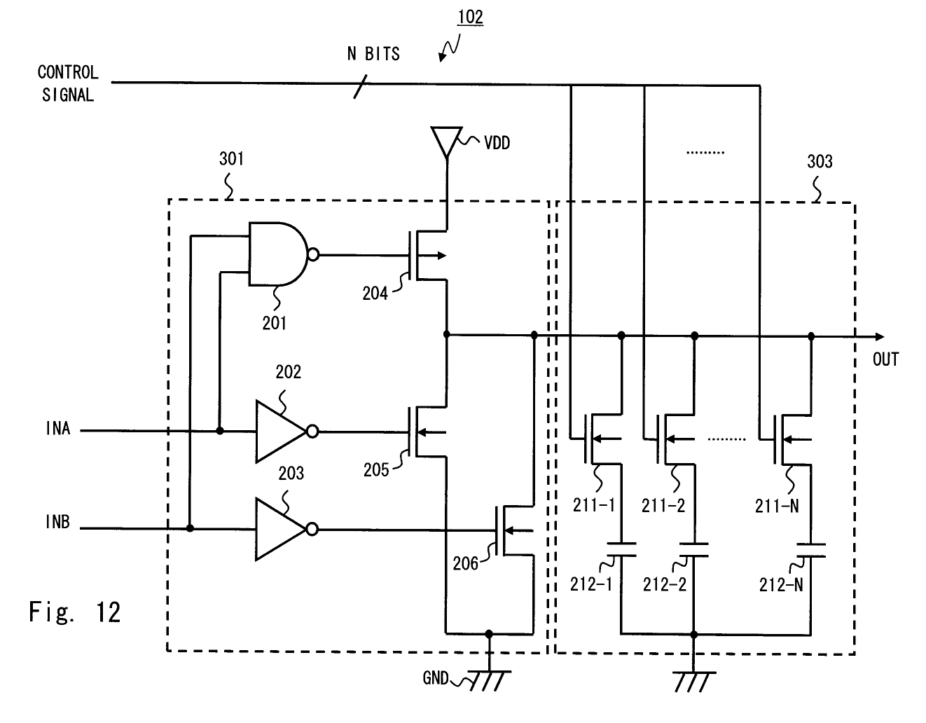

FIGS. 11 and 12 each show an example of the phase interpolation circuit 102. First, the phase interpolation circuit 102 shown in FIG. 11 will be described. The circuit shown in FIG. 11 includes a NAND 201, an inverter 202, an inverter 203, a transistor (first transistor) 204, a transistor (second transistor) 205, a transistor (third transistor) 206, a constant current source (first constant current source) 207, and a constant current source (second constant current source) 208. The NAND 201, the inverters 202 and 203, and the transistors 204, 205 and 206 constitute an interpolation signal generation circuit 301. Further, the constant current sources 207 and 208 constitute an interpolation signal adjustment circuit 302. Note that the transistor 204 is a P-channel MOS transistor, and the transistors 205 and 206 are N-channel MOS transistors.

A clock input terminal INA of the phase interpolation circuit 102 is connected to one input terminal of the NAND 201 and an input terminal of the inverter 202. A clock input terminal NB of the phase interpolation circuit 102 is connected to the other input terminal of the NAND 201 and an input terminal of the inverter 203. An output terminal of the NAND 201 is connected to a gate of the transistor 204. An output terminal of the inverter 202 is connected to a gate of the transistor 205. An output terminal of the inverter 203 is connected to a gate of the transistor 206. A control signal input terminal of the phase interpolation circuit 102 is connected to control terminals of the constant current sources 207 and 208.

A source of the transistor 204 is connected to a power supply voltage VDD. A drain of the transistor 204 is connected to a drain of the transistor 205, a drain of the transistor 206, and an external output terminal OUT of the phase interpolation circuit 102. A source of the transistor 205 is connected to an input terminal of the constant current source 207. A source of the transistor 206 is connected to an input terminal of the constant current source 208. An output terminal of the constant current source 207 and an output terminal of the constant current source 208 are connected to a ground voltage GND.

The circuit shown in FIG. 11 receives the two clock signals output from the selection circuit 107 as described above. It is assumed, in this example, that the clock signal 1 is supplied to the clock input terminal INA and the clock signal 2 is supplied to the clock input terminal INB. The current that flows between the source and the drain of the transistor 204 is controlled based on the clock signals 1 and 2. The current that flows between the source and the drain of the transistor 205 is controlled based on the clock signal 1. The current that flows between the source and the drain of the transistor 206 is controlled based on the clock signal 2.

The voltage level of a node that connects the drain of the transistor 204, the drain of the transistor 205, and the drain of the transistor 206 is output as the interpolation signal.

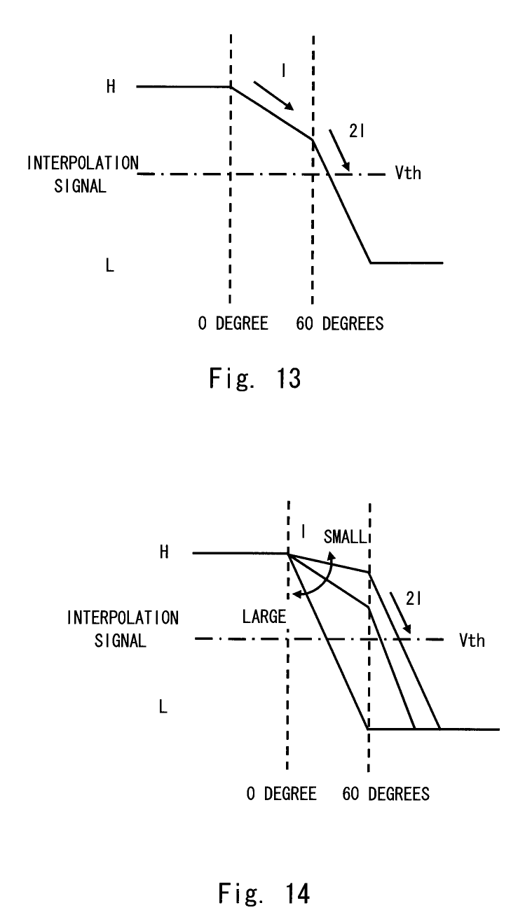

FIGS. 13 and 14 each show a signal waveform of the interpolation signal. When the clock signals 1 and 2 are both H in the circuit shown in FIG. 11, the transistor 204 is controlled to ON. On the other hand, the transistors 205 and 206 are controlled to OFF. Hence, the interpolation signal indicates H.

When the clock signal 1 is L and the clock signal 2 is H, the transistors 204 and 206 are controlled to OFF. On the other hand, the transistor 205 is controlled to ON. Hence, the interpolation signal is changed from H to L. Now, the current that flows when the transistor 205 is turned on is represented by I. Further, the current that flows when the transistor 206 is turned on is represented by I. In summary, the transistors 205 and 206 are controlled so that the values of the currents that flow when the transistors 205 and 206 are ON become the same. In this case, the charge stored between the phase interpolation circuit 102 and the cell at the subsequent stage is discharged by the current I that flows through the transistor 205. As shown in FIG. 13, the charge is discharged by the current I from the falling edge of the clock signal 1 (at the point of phase of 0 degrees) to the falling edge of the clock signal 2 (at the point of phase of 60 degrees).

When the clock signals 1 and 2 are both L, the transistor 204 is controlled to OFF. On the other hand, the transistors 205 and 206 are controlled to ON. Hence, the interpolation signal indicates L. In this case, the charge stored between the phase interpolation circuit 102 and the cell at the subsequent stage is discharged by the current 2I that flows through the transistors 205 and 206. In this case, the inclination of the signal change of the interpolation signal from H to L is greater than the case where the clock signal 1 is L and the clock signal 2 is H. In other words, in this case, the change of the interpolation signal from H to L is faster. As shown in FIG. 13, the charge is discharged by the current 2I from the falling edge of the clock signal 2 (at the point of phase of 60 degrees) to the rising edge that the clock signal 1 is raised next (not shown).

The circuit shown in FIG. 11 further includes the constant current sources 207 and 208. The circuit shown in FIG. 11 controls the current I that flows through each of the constant current sources 207 and 208 based on the first control signal output from the control circuit 103a. In other words, the circuit shown in FIG. 11 controls the current I that flows through each of the transistors 205 and 206 based on the first control signal output from the control circuit 103a. The circuit shown in FIG. 11 thus controls the inclination of the signal change of the interpolation signal by controlling the value of the current I as shown in FIG. 14. Accordingly, the circuit shown in FIG. 11 is able to generate the interpolation signal with high accuracy.

Next, the phase interpolation circuit 102 shown in FIG. 12 will be described. The circuit shown in FIG. 12 does not include the constant current sources 207 and 208 unlike the circuit shown in FIG. 11. In summary, the source of the transistor 205 and the source of the transistor 206 are directly connected to the ground voltage GND. The circuit shown in FIG. 12 further includes N (N is a natural number) transistors 211-1 to 211-N and N capacitance elements 212-1 to 212-N in addition to the circuit components shown in FIG. 11. The transistors 211-1 to 211-N and the N capacitance elements 212-1 to 212-N constitute an interpolation signal adjustment circuit 303.

The capacitance elements 212-1 to 212-N are connected in parallel between the node that connects the drains of the transistors 204, 205, and 206, and the ground voltage GND. The transistors 211-1 to 211-N are connected in series with the respective capacitance elements 212-1 to 212-N. The transistors 211-1 to 211-N are turned on or off according to the first control signal output from the control circuit 103a. The other circuit components are similar to those shown in FIG. 11, and thus description thereof will be omitted.

Note that the transistors 211-1 to 211-N are N-channel MOS transistors. Further, the capacitance elements 212-1 to 212-N have the same capacitance value. The first control signal has an N-bit width. The voltages of the bit lines are applied to the respective gates of the transistors 211-1 to 211-N. The circuit shown in FIG. 12 controls ON/OFF of the transistors 211-1 to 211-N, so as to control the capacitance value that is loaded between the phase interpolation circuit 102 and the cell at the subsequent stage. Accordingly, the circuit shown in FIG. 12 controls the current I that flows through each of the transistors 205 and 206. The circuit shown in FIG. 12 thus controls the inclination of the signal change of the interpolation signal by controlling the value of the current I, as shown in FIG. 14. Accordingly, the circuit shown in FIG. 12 is able to generate the interpolation signal with high accuracy.

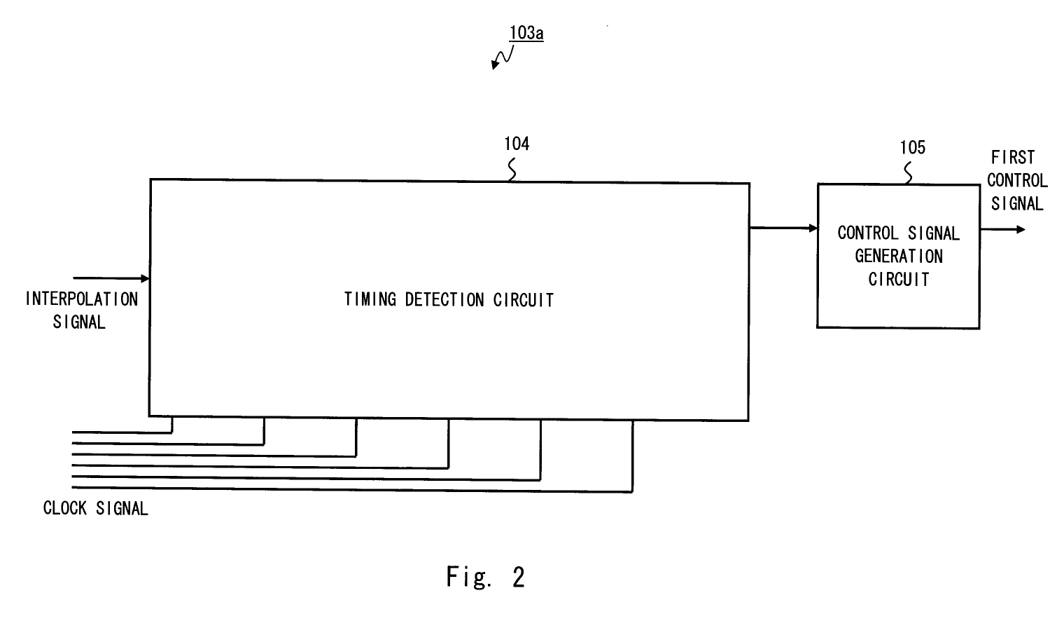

FIG. 2 shows the control circuit 103a. The circuit shown in FIG. 2 includes a timing detection circuit 104 and a control signal generation circuit 105. The clock signals 1 to 6 output from the PLL circuit 101 are input to clock input terminals of the timing detection circuit 104. Further, the interpolation signal output from the phase interpolation circuit 102 is input to an interpolation signal input terminal of the timing detection circuit 104. The signal output from the timing detection circuit 104 is supplied to the control signal generation circuit 105. The control signal generation circuit 105 outputs the first control signal to the phase interpolation circuit 102.

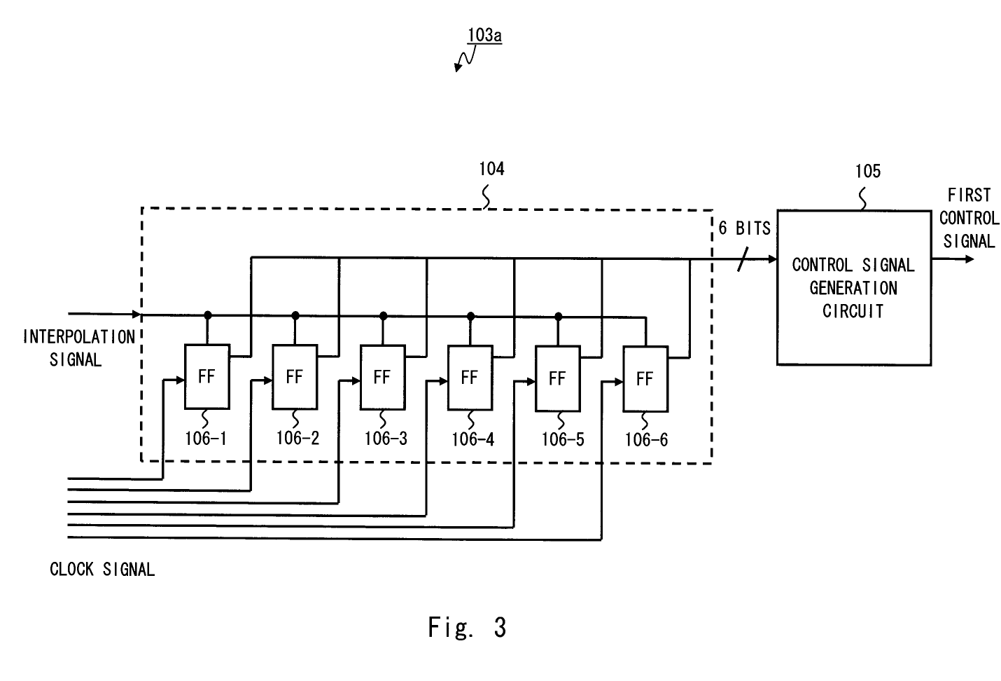

A specific example of the timing detection circuit 104 shown in FIG. 2 will be described with reference to FIG. 3. The timing detection circuit 104 includes six-stage flip-flops (hereinafter simply referred to as FFs) 106-1 to 106-6, for example. The clock signal 1 is input to a clock input terminal of the FF106-1. The clock signal 2 is input to a clock input terminal of the FF106-2. The clock signal 3 is input to a clock input terminal of the FF106-3. The clock signal 4 is input to a clock input terminal of the FF106-4. The clock signal 5 is input to a clock input terminal of the FF106-5. The clock signal 6 is input to a clock input terminal of the FF106-6. The interpolation signal output from the phase interpolation circuit 102 is supplied to data input terminals of the FFs 106-1 to 106-6. Signals output from data output terminals of the FFs 106-1 to 106-6 are supplied to the control signal generation circuit 105.

The timing detection circuit 104 synchronously detects the interpolation signal with the six clock signals having different phases with each other. Hence, the timing detection circuit 104 is able to detect the timing of the change in the logic value of the interpolation signal. Then, the control signal generation circuit 105 generates a first control signal based on the detection result in the timing detection circuit 104, and outputs the first control signal to the phase interpolation circuit 102. In short, the timing of the change in the logic value (inclination of the signal change) of the interpolation signal output from the phase interpolation circuit 102 is controlled by the detection result in the timing detection circuit 104. In other words, the phase of the interpolation signal is controlled by the detection result in the timing detection circuit 104. The threshold voltage of the FFs 106-1 to 106-6 and the threshold voltage of the cell at the subsequent stage of the phase interpolation circuit 102 are preferably the same.

As described above, the multi-phase clock generation circuit 100a according to the first exemplary embodiment of the present invention includes the control circuit 103a, thereby automatically detecting the inclination of the change of the interpolation signal and generating the interpolation signal with high accuracy. In summary, the multi-phase clock generation circuit 100a need not control the interpolation signal by the control signal that is supplied from outside. Further, the multi-phase clock generation circuit 100a is able to control the interpolation signal regardless of the frequencies of the clock signals that are the target of the phase interpolation. In short, the multi-phase clock generation circuit 100a need not include a circuit or the like to measure the frequencies of the clock signals. Accordingly, the multi-phase clock generation circuit 100a is able to suppress the increase in the size of the circuit. In addition, the control circuit 103a is able to directly judge the interpolation signal that is output. Hence, by directly judging the interpolation signal including influences of the temperature, the power supply voltage, and the manufacturing process, the optimal first control signal considering the influences can be generated.

The method of controlling the interpolation signal will be described further in detail. In this example, description will be made of a case in which the multi-phase clock generation circuit 100a includes the phase interpolation circuit 102 as shown in FIG. 11.

First, description is made of a case where two clock signals having no phase difference are input to the circuit as shown in FIG. 11. At this time, a delay time from when the phase interpolation circuit 102 receives the clock signals to when it outputs the interpolation signal is represented by Thomo. Further, the threshold voltage of the cell (buffer, for example) at the subsequent stage of the phase interpolation circuit 102 is represented by Vth. Furthermore, the capacitance that is loaded between the phase interpolation circuit 102 and the cell at the subsequent stage is represented by Cth. Further, the current that flows when the transistor 205 is ON is represented by I. Similarly, the current that flows when the transistor 206 is ON is represented by I. In this case, the following expression is established.

Thomo=Cth·Vth/2I (1)

Next, description will be made of a case in which two clock signals having different phases are input to the circuit as shown in FIG. 11. The clock signal 1 is supplied to the clock input terminal INA, and the clock signal 2 is supplied to the clock input terminal INB. The phase difference between the two clock signals is represented by Tdiff. The delay time of the interpolation signal at this time is represented by Thetero.

First, the logic value of only the clock signal 1 is changed (fallen), which turns on the transistor 205. Hence, the charge stored between the phase interpolation circuit 102 and the cell at the subsequent stage is discharged by the current I. After that, the logic value of the clock signal 2 is changed (fallen), which turns on the transistor 206 as well. Hence, the remaining charge stored between the phase interpolation circuit 102 and the cell at the subsequent stage is discharged by the current 2I.

Accordingly, the delay time of the interpolation signal Thetero can be represented by time Tdiff which indicates the time for discharging by the current I and the time for discharging the remaining charge by the current 2I. In short, the following expression is established.

$$\begin{matrix}Thetero = Tdiff + ( Cth \cdot Vth - I \cdot Tdiff ) / 2 I \\ = Thomo + Tdiff / 2\end{matrix} \qquad ( 2 )$$

This means that the phase interpolation circuit 102 generates an interpolation signal obtained by adding half the delay of the phase difference Tdiff to the delay Thomo of the signal output when the signals having the same phase is input, i.e., an interpolation signal of 50%.

Now, the phase interpolation circuit 102 needs to control the phase of the interpolation signal to satisfy the following two conditions. The first condition (hereinafter simply referred to as condition 1) is expressed as 0<Cth·Vth−I·Tdiff. This means that the phase interpolation circuit 102 needs to control the potential of the interpolation signal so as not to decrease the potential equal to or below the threshold voltage Vth while only the clock signal 1 indicates L (charge is discharged only by the current I). If this condition is not satisfied, the phase interpolation circuit 102 cannot control the phase of the interpolation signal by the clock signal 2.

The second condition (hereinafter simply referred to as condition 2) is expressed as (Cth·Vth−I·Tdiff)/2I<Tover, where Tover represents the time during which both of the clock signals 1 and 2 indicate L. In summary, the phase interpolation circuit 102 needs to control the potential of the interpolation signal to reduce the potential equal to or below the threshold voltage Vth while both of the clock signals 1 and 2 indicate L (while charge is discharged by the current 2I). If this condition is not satisfied, the phase interpolation circuit 102 cannot change the logic value of the interpolation signal before the clock signal 1 is raised next.

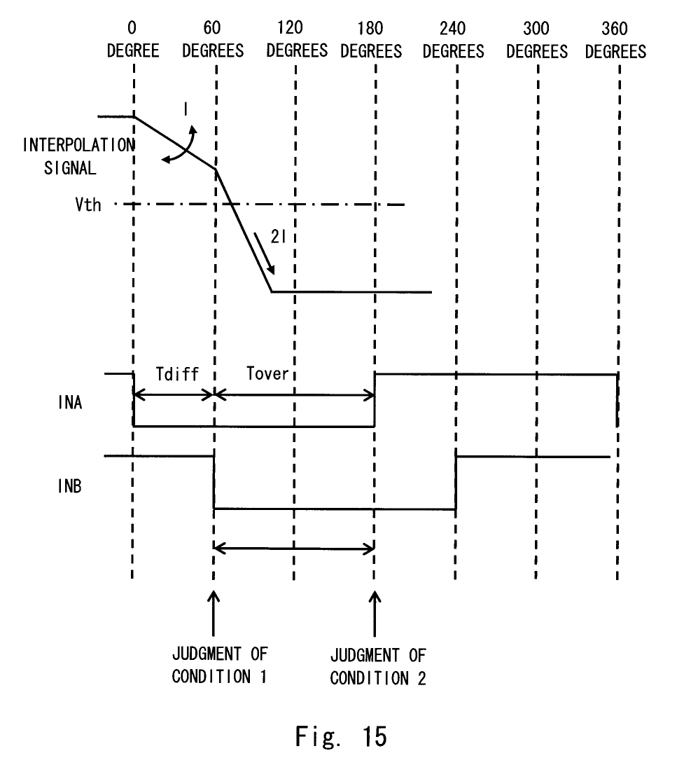

Referring to FIG. 15, the method of detecting the timing detection circuit 104 will be described further in detail. Note that the clock input terminal INA receives the clock signal 1, and the clock input terminal INB receives the clock signal 2. Further, the phase difference between the clock signal 1 and the clock signal 2 is 60 degrees.

Whether the interpolation signal satisfies the condition 1 can be determined by the potential of the interpolation signal at a falling edge of the clock signal 2 (at the phase of 60 degrees). Specifically, when the potential of the interpolation signal is larger than the threshold voltage Vth, the interpolation signal satisfies the condition 1. On the other hand, when the potential of the interpolation signal is equal to or smaller than the threshold voltage Vth, the interpolation signal does not satisfy the condition 1. More specifically, when the detection result in the FF106-2 provided in the timing detection circuit 104 shown in FIG. 3 is H, the interpolation signal satisfies the condition 1. On the other hand, when the detection result in the FF106-2 is L, the interpolation signal does not satisfy the condition 1. When the interpolation signal does not satisfy the condition 1, the control signal generation circuit 105 outputs the first control signal to reduce the current I. Therefore, the inclination of the signal change of the interpolation signal becomes smaller.

Next, whether the interpolation signal satisfies the condition 2 can be determined by the potential of the interpolation signal at a rising edge of the clock signal 1 (at the phase of 180 degrees). Specifically, when the potential of the interpolation signal is smaller than the threshold voltage Vth, the interpolation signal satisfies the condition 2. On the other hand, when the potential of the interpolation signal is equal to or larger than the threshold voltage Vth, the interpolation signal does not satisfy the condition 2. More specifically, when the detection result in the FF106-4 provided in the timing detection circuit 104 shown in FIG. 3 is L, the interpolation signal satisfies the condition 2. On the other hand, when the detection result in the FF106-4 is H, the interpolation signal does not satisfy the condition 2. When the interpolation signal does not satisfy the condition 2, the control signal generation circuit 105 outputs the first control signal to increase the current I. Therefore, the inclination of the signal change of the interpolation signal becomes larger.

In summary, when the conditions 1 and 2 are both satisfied, the output of the FF106-2 shown in FIG. 3 indicates H, and the output of the FF106-4 indicates L. Naturally, when the output of the FF106-3 shown in FIG. 3 is L, the interpolation signal satisfies the condition 2. The control circuit 103a outputs the first control signal to the phase interpolation circuit 102 so that the interpolation signal satisfies both of the conditions 1 and 2.

As described above, the multi-phase clock generation circuit 100a according to the first exemplary embodiment of the present invention includes the control circuit 103a, thereby automatically controlling the inclination of the signal change of the interpolation signal and generating the interpolation signal with high accuracy. In short, the multi-phase clock generation circuit 100a need not control the interpolation signal by the control signal that is supplied from outside. Further, the multi-phase clock generation circuit 100a is able to control the interpolation signal regardless of the frequencies of the clock signals that are the target of the phase interpolation. In short, the multi-phase clock generation circuit 100a need not include the circuit to measure the frequencies of the clock signals. Accordingly, the multi-phase clock generation circuit 100a is able to suppress the increase in the size of the circuit. Further, by automatically controlling the inclination of the interpolation signal including the influences of the temperature, the power supply voltage, and the manufacturing process, these influences can be cancelled.

### Second Exemplary Embodiment

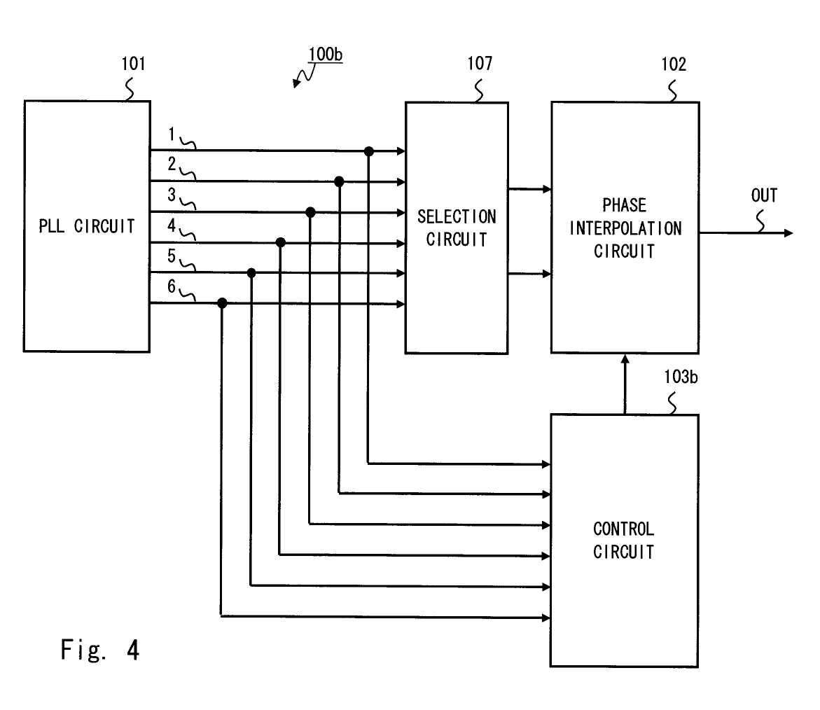

FIG. 4 shows a multi-phase clock generation circuit 100b according to a second exemplary embodiment of the present invention. The multi-phase clock generation circuit 100b shown in FIG. 4 is different from the multi-phase clock generation circuit 100a shown in FIG. 1 in that the multi-phase clock generation circuit 100b includes a control circuit 103b instead of the control circuit 103a. The control circuit 103b does not receive the interpolation signal output from the phase interpolation circuit 102. The other circuit components and operations are similar to those in the first exemplary embodiment, and thus description thereof will be omitted.

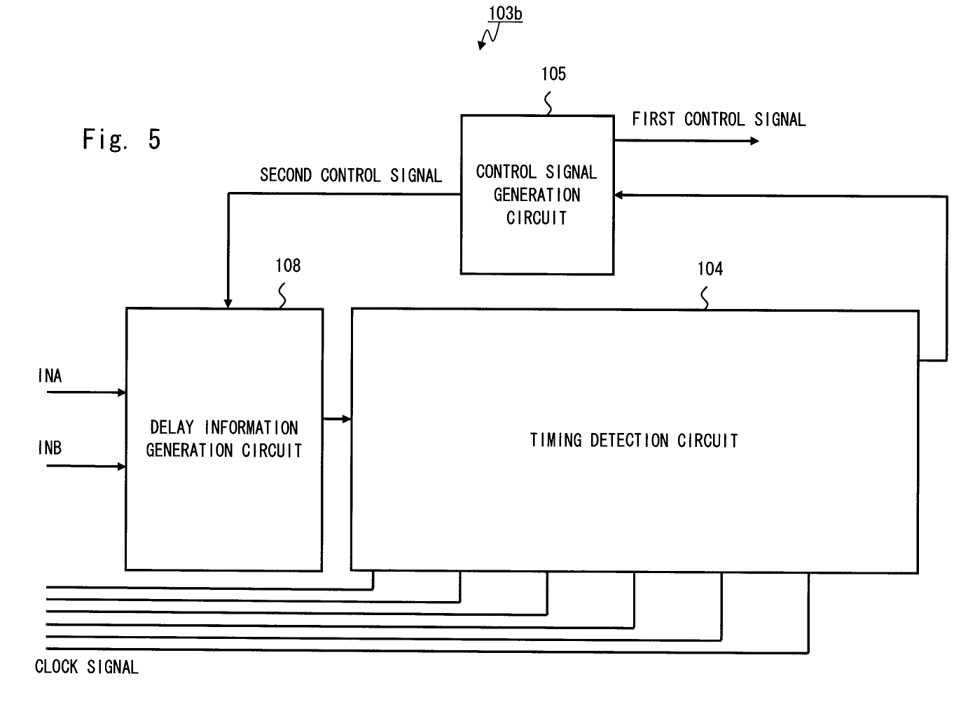

FIG. 5 shows the control circuit 103b. The control circuit 103b shown in FIG. 5 includes a delay information generation circuit 108 in addition to the components of the control circuit 103a shown in FIG. 2. The control signal generation circuit 105 outputs a second control signal to the delay information generation circuit 108. Alternatively, the control signal generation circuit 105 may output the first control signal to the delay information generation circuit 108 instead of outputting the second control signal.

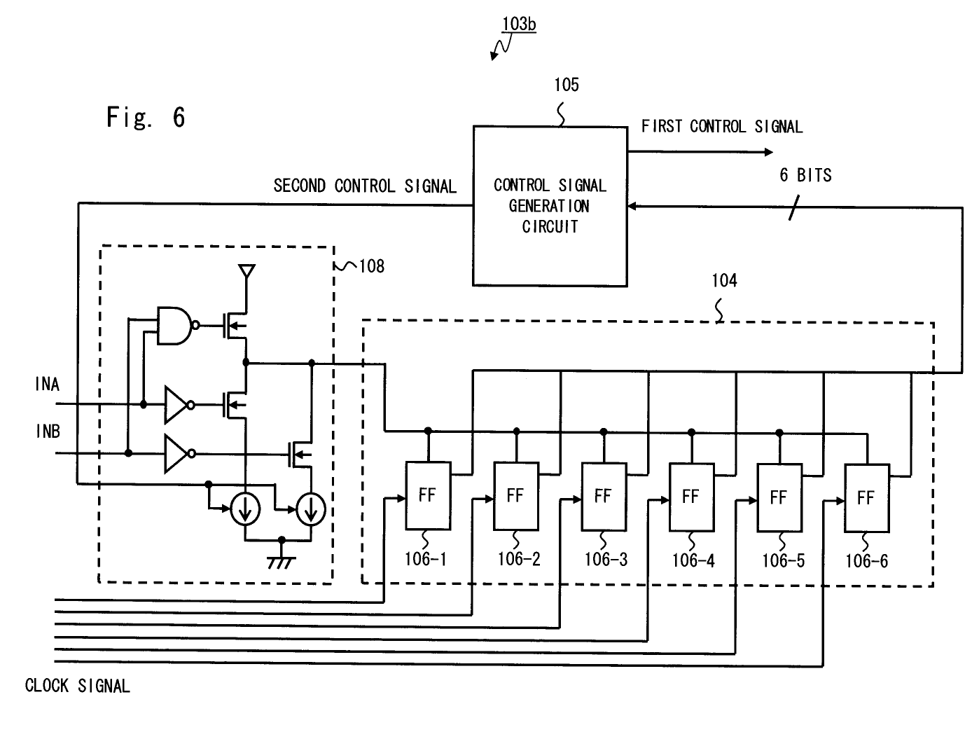

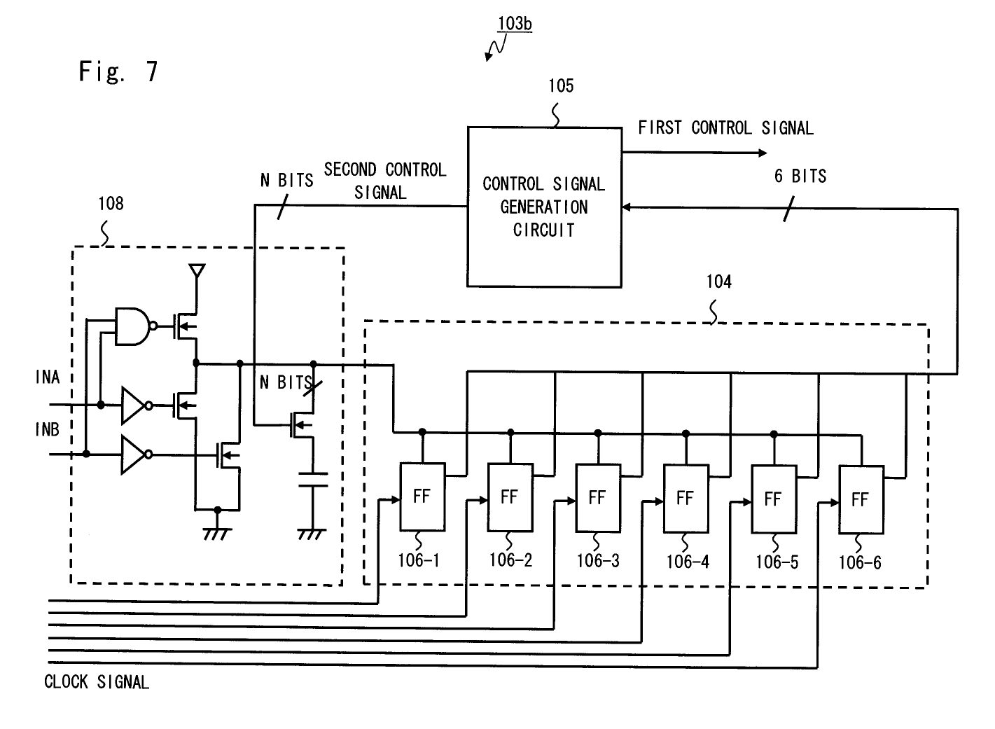

The delay information generation circuit 108 generates a sampling signal according to the phase difference between the two clock signals that are supplied. The timing detection circuit 104 detects the timing of the change in the logic value of the sampling signal generated by the delay information generation circuit 108. The control signal generation circuit 105 outputs first and second control signals based on the detection result in the timing detection circuit 104. The delay information generation circuit 108 may have the same circuit configuration as that of the phase interpolation circuit 102 shown in FIG. 11, as shown in FIG. 6, for example. Further, the delay information generation circuit 108 may have the same circuit configuration as that of the phase interpolation circuit 102 shown in FIG. 12, as shown in FIG. 7. For example, the delay information generation circuit 108 may output a sampling signal that corresponds to the interpolation signal.

As stated above, the multi-phase clock generation circuit 100b according to the second exemplary embodiment of the present invention controls the inclination of the signal change of the interpolation signal based on the sampling signal output from the delay information generation circuit 108 instead of the interpolation signal output from the phase interpolation circuit 102. Accordingly, the similar effect as the multi-phase clock generation circuit 100a according to the first exemplary embodiment of the present invention can be achieved.

### Third Exemplary Embodiment

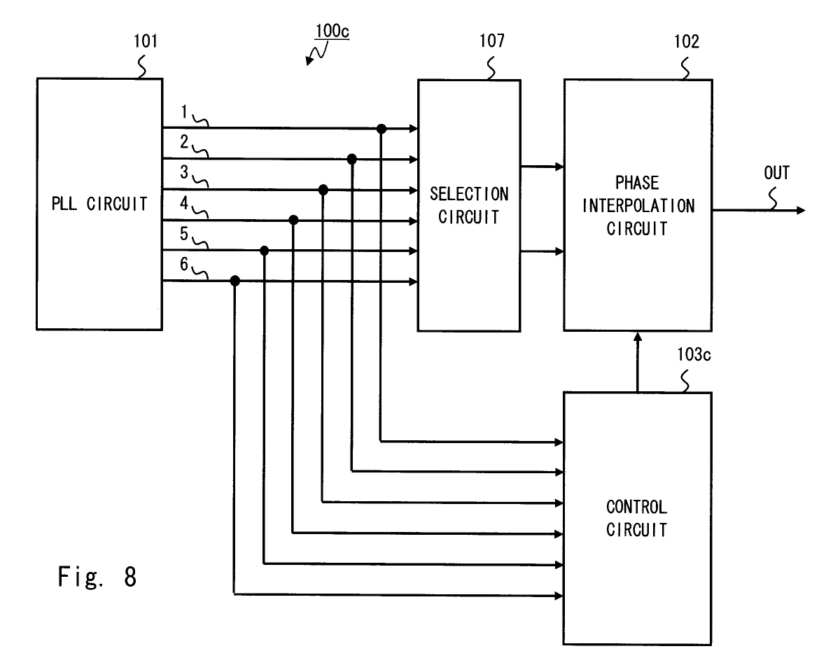

FIG. 8 shows a multi-phase clock generation circuit 100c according to a third exemplary embodiment of the present invention. In the multi-phase clock generation circuit 100b according to the second exemplary embodiment, two clock signals are input to the delay information generation circuit 108. On the other hand, in the multi-phase clock generation circuit 100c according to the third exemplary embodiment, one clock signal and a predetermined fixed signal are input to the delay information generation circuit 108. In short, the multi-phase clock generation circuit 100c controls the interpolation signal based on one clock signal.

The delay information generation circuit 108 delays one clock signal that is received to generate a sampling signal. The timing detection circuit 104 then detects the timing of the change in the logic value of the sampling signal generated by the delay information generation circuit 108. The other circuit components are similar to those in the second exemplary embodiment, and thus description will be omitted.

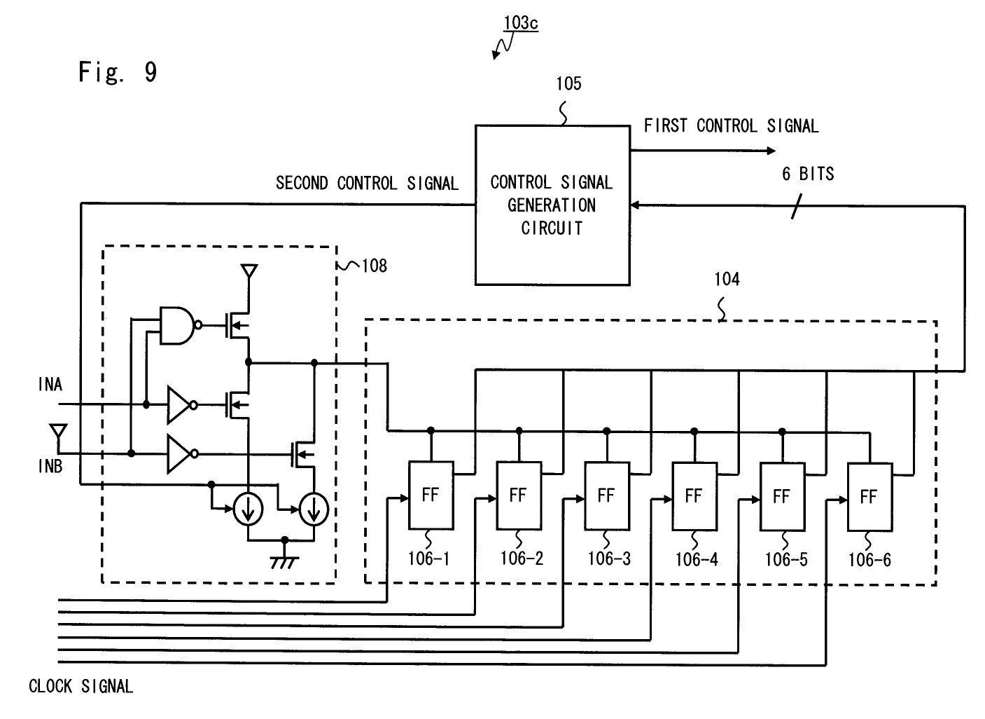

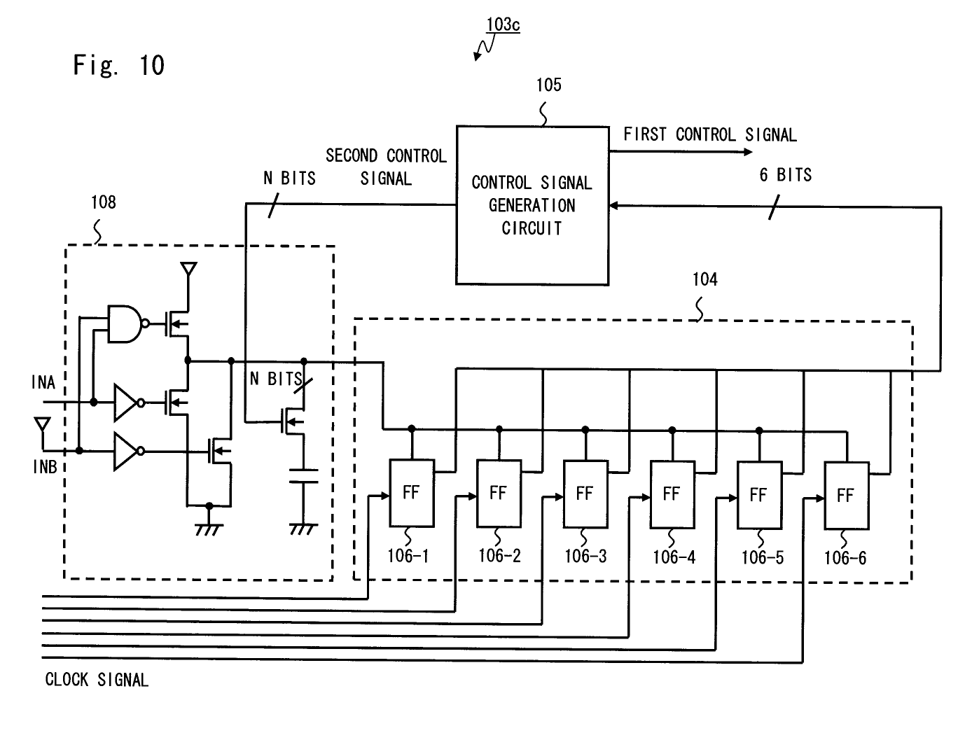

The delay information generation circuit 108 may have the same configuration as that of the phase interpolation circuit 102 shown in FIG. 11, as shown in FIG. 9, for example. Alternatively, the delay information generation circuit 108 may have the same configuration as that of the phase interpolation circuit 102 shown in FIG. 12, as shown in FIG. 10, for example. For example, the delay information generation circuit 108 may output the sampling signal that corresponds to the interpolation signal.

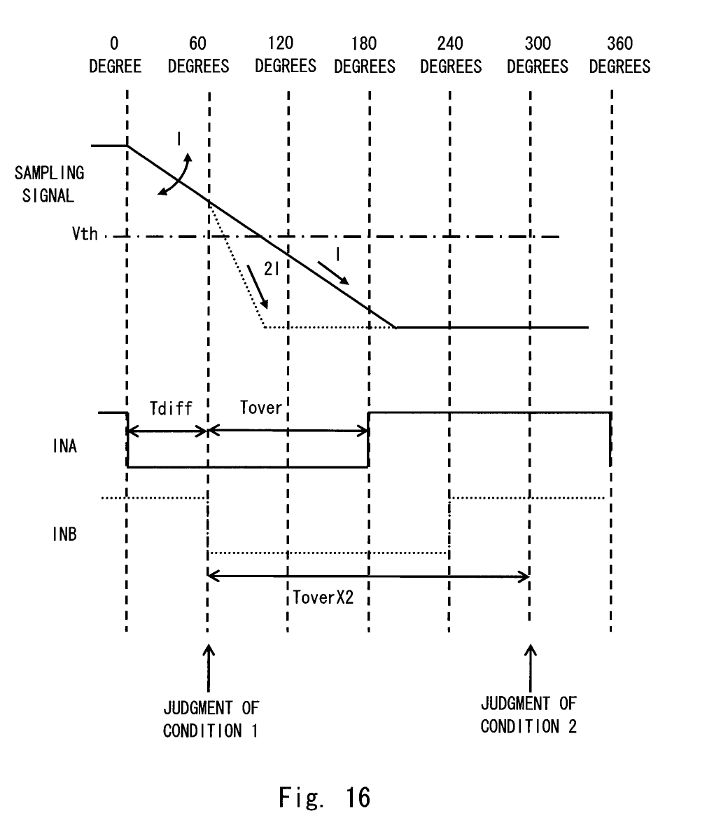

A detection method in the timing detection circuit 104 will be described with reference to FIG. 16. Description will be made of a case where the control circuit 103c shown in FIG. 9 is used. The clock input terminal INA of the phase interpolation circuit 102 receives the clock signal 1, and the clock input terminal INB of the phase interpolation circuit 102 receives the clock signal 2. The phase difference between the clock signal 1 and the clock signal 2 is 60 degrees. Further, the clock input terminal INA of the delay information generation circuit 108 receives the clock signal 1, and the clock input terminal INB of the delay information generation circuit 108 receives an H-level fixed signal.

Whether the interpolation signal satisfies the condition 1 can be determined by the potential of the sampling signal at a falling edge of the clock signal 2 (at the phase of 60 degrees). Specifically, when the potential of the sampling signal is larger than the threshold voltage Vth, the interpolation signal satisfies the condition 1. On the other hand, when the potential of the sampling signal is equal to or smaller than the threshold voltage Vth, the interpolation signal does not satisfy the condition 1. More specifically, when the detection result in the FF106-2 provided in the timing detection circuit 104 shown in FIG. 9 is H, the interpolation signal satisfies the condition 1. On the other hand, when the detection result in the FF106-2 is L, the interpolation signal does not satisfy the condition 1. When the interpolation signal does not satisfy the condition 1, the control signal generation circuit 105 outputs the second control signal to reduce the current I. Accordingly, the inclination of the signal change of the sampling signal becomes smaller.

Next, a method of determining whether the interpolation signal satisfies the condition 2 will be described. The input terminal INB of the delay information generation circuit 108 receives an H-level fixed signal. Hence, when the clock signal 1 is L, the charge stored in the output side of the delay information generation circuit 108 is always discharged by the current I. In short, the inclination of the signal change of the sampling signal from H to L is always constant.

The inclination of the signal change by the current I is half the inclination of the signal change by the current 2I. In this case, as shown in FIG. 16, it can be determined by the potential of the sampling signal after time Tover×2 is passed from the phase of 60 degrees whether the interpolation signal satisfies the condition 2. In short, it can be determined by the potential of the sampling signal at the phase of 300 degrees whether the interpolation signal satisfies the condition 2. As already described above, the time during which both of the clock signals 1 and 2 indicate L is represented by Tover.

When the potential of the sampling signal at the phases of 120 and 180 degrees is equal to or less than the threshold voltage Vth, the interpolation signal naturally satisfies the condition 2. Typically, in this case, it is determined by the potential of the sampling signal at the phases of 120 and 180 degrees whether the interpolation signal satisfies the condition 2.

Meanwhile, when the potential of the sampling signal at the phase of 300 degrees is detected, the clock signal 1 is raised at the phase of 180 degrees. In this case, the rising of the clock signal 1 supplied to the delay information generation circuit 108 needs to be controlled. In the following description, it is assumed that such control is executed.

When the potential of the sampling signal is smaller than the threshold voltage Vth at the phase of 300 degrees, the interpolation signal satisfies the condition 2. On the other hand, when the potential of the sampling signal is equal to or more than the threshold voltage Vth, the interpolation signal does not satisfy the condition 2. Specifically, when the detection result in the FF106-6 provided in the timing detection circuit 104 shown in FIG. 9 is L, the interpolation signal satisfies the condition 2. On the other hand, when the detection result in the FF106-6 is H, the interpolation signal does not satisfy the condition 2. When the interpolation signal does not satisfy the condition 2, the control signal generation circuit 105 outputs the second control signal to increase the current I. Accordingly, the inclination of the signal change of the sampling signal increases.

In summary, when the conditions 1 and 2 are both satisfied, the output of the FF106-2 shown in FIG. 9 indicates H, and the output of the FF106-6 shown in FIG. 9 indicates L. The control circuit 103c outputs the first control signal to the phase interpolation circuit 102 so that the interpolation signal satisfies both of the conditions 1 and 2.

As described above, the multi-phase clock generation circuit 100c according to the third exemplary embodiment of the present invention includes the delay information generation circuit 108 that generates the sampling signal based on only one clock signal. Accordingly, the similar effect as the multi-clock generation circuit 100a according to the first exemplary embodiment of the present invention may be achieved.

Note that the present invention is not limited to the exemplary embodiments described above, but may be changed as appropriate without departing from the spirit of the present invention. For example, described above is the operation when the multi-phase clock generation circuit includes the phase interpolation circuit 102 shown in FIG. 11; however, it is not limited to this case. The multi-phase clock generation circuit may include the phase interpolation circuit 102 shown in FIG. 12. In this case, the inclinations of the changes of the interpolation signal and the sampling signal are controlled by controlling the capacitance values 212-1 to 212-N loaded to the output side of the phase interpolation circuit 102 shown in FIG. 12.

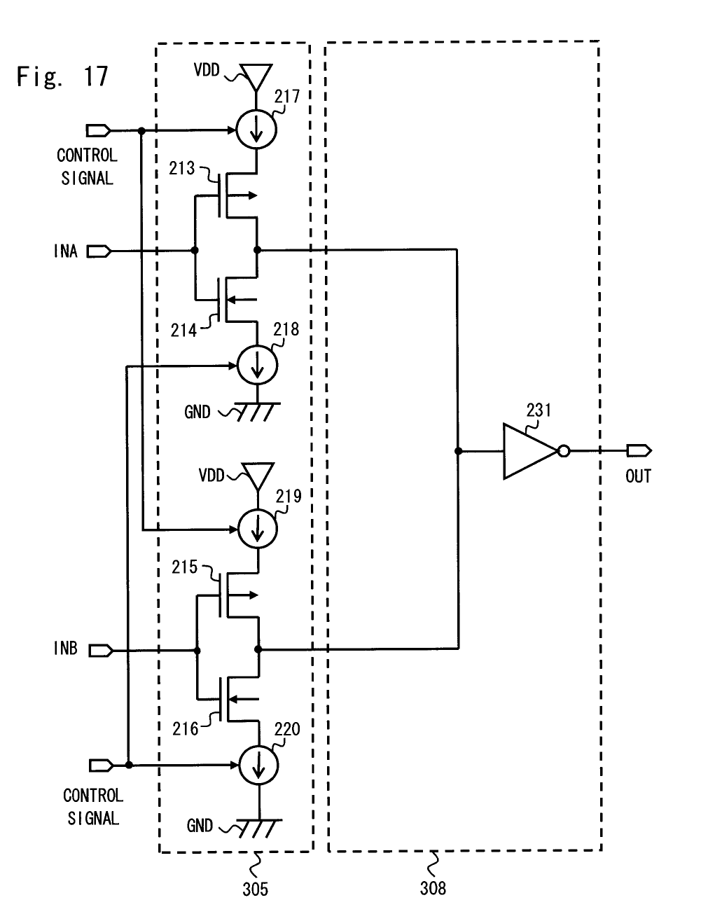

Further, the phase interpolation circuit 102 is not limited to the circuits shown in FIGS. 11 and 12. The phase interpolation circuit 102 may have any circuit configuration as long as it includes an interpolation signal generation circuit that generates an interpolation signal based on two input signals and an interpolation signal adjustment circuit that adjusts the inclination of the signal change of the interpolation signal by the control signal. For example, the phase interpolation circuit may be a circuit as shown in FIGS. 17 to 19. FIGS. 17 to 19 each show a phase interpolation circuit of inverter short-circuit type.

The circuit shown in FIG. 17 includes an interpolation signal adjustment circuit 305 that adjusts the inclinations of the signal changes of the clock signals which are supplied based on the first control signal, and an interpolation signal generation circuit 308 that generates the interpolation signal according to the clock signals that are adjusted. Specifically, the interpolation signal generation circuit 308 includes an inverter 231. The interpolation signal adjustment circuit 305 includes transistors 213 to 216 and constant current sources 217 to 220. The transistors 213 and 214 form an inverter. The current flowing through the transistor 213 is controlled by the constant current source 217. The current flowing through the transistor 214 is controlled by the constant current source 218. One clock signal is applied to gates of the transistors 213 and 214 through an input terminal INA. The potential of a node that connects a drain of the transistor 213 and a drain of the transistor 214 (output of the inverter composed of the transistors 213 and 214) is input to the inverter 231.

In the similar way, the transistors 215 and 216 form an inverter. The current flowing through the transistor 215 is controlled by the constant current source 219. The current flowing through the transistor 216 is controlled by the constant current source 220. The other clock signal is applied to gates of the transistors 215 and 216 through an input terminal INB. The potential of a node that connects a drain of the transistor 215 and a drain of the transistor 216 (output of the inverter composed of the transistors 215 and 216) is supplied to the inverter 231. In summary, the output signal of the inverter composed of the transistors 213 and 214 and the output signal of the inverter composed of the transistors 215 and 216 short-circuit and are input to the inverter 231. The inverter 231 generates the interpolation signal according to the input signals. Note that the output currents of the constant current sources 217 to 220 are controlled by the first control signal generated by the control signal generation circuit 105.

In this way, the circuit shown in FIG. 17 adjusts the inclinations of the signal changes of the clock signals that are supplied by the interpolation signal adjustment circuit 305, thereby generating the interpolation signal with high accuracy. Such a circuit configuration may be applied to the third exemplary embodiment.

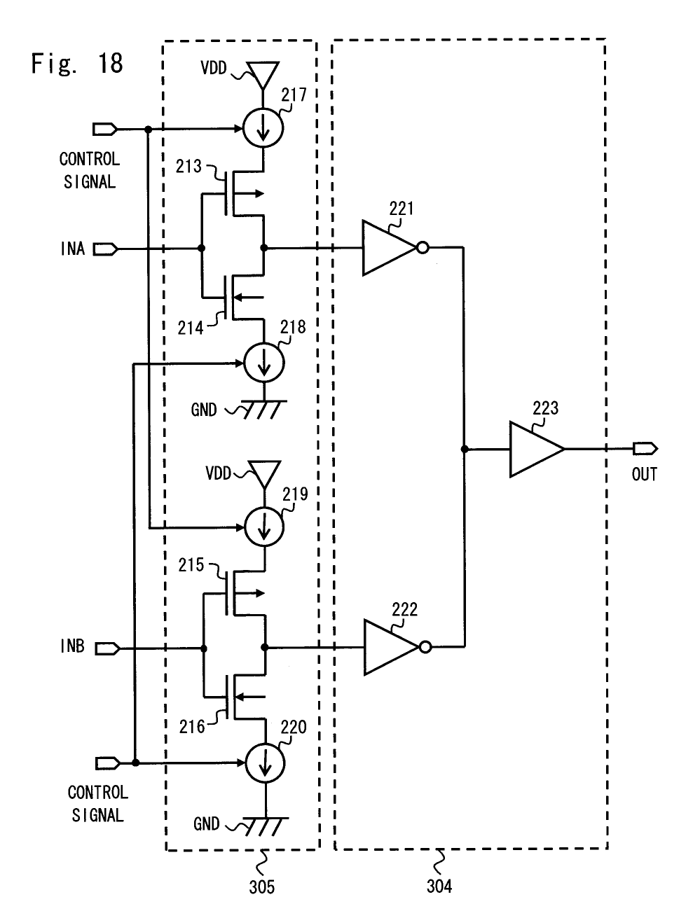

The circuit shown in FIG. 18 includes an interpolation signal adjustment circuit 305 that adjusts the inclinations of the signal changes of the clock signals that are supplied based on the first control signal, and an interpolation signal generation circuit 304 that generates the interpolation signal according to the clock signals that are adjusted. More specifically, the interpolation signal generation circuit 304 includes inverters 221 and 222 and a buffer 223. The circuit configuration of the interpolation signal adjustment circuit 305 is similar to that shown in FIG. 17, and thus description thereof will be omitted. The potential of a node that connects a drain of the transistor 213 and a drain of the transistor 214 (output of the inverter composed of the transistors 213 and 214) is input to the inverter 221. In the similar way, the potential of a node that connects a drain of the transistor 215 and a drain of the transistor 216 (output of the inverter composed of transistors 215 and 216) is input to the inverter 222. The output signal of the inverter 221 and the output signal of the inverter 222 short-circuit and are input to the buffer 223. The buffer 223 generates the interpolation signal according to the output signals of the inverters 221 and 222.

The circuit shown in FIG. 18 controls the inclinations of the signal changes of the clock signals that are supplied by the interpolation signal adjustment circuit 305 as is similar to the circuit shown in FIG. 17, thereby generating the interpolation signal with high accuracy. As described above, the multi-phase clock generation circuit according to the third exemplary embodiment may be applied to a circuit configuration that includes a phase interpolation circuit of inverter short-circuit type. When the multi-phase clock generation circuit employs the circuit shown in FIGS. 17 and 18 as a phase interpolation circuit, the timing detection circuit 104 may be used as a circuit that detects the timing of the change in the logic value of the output signals of the interpolation signal adjustment circuit 305.

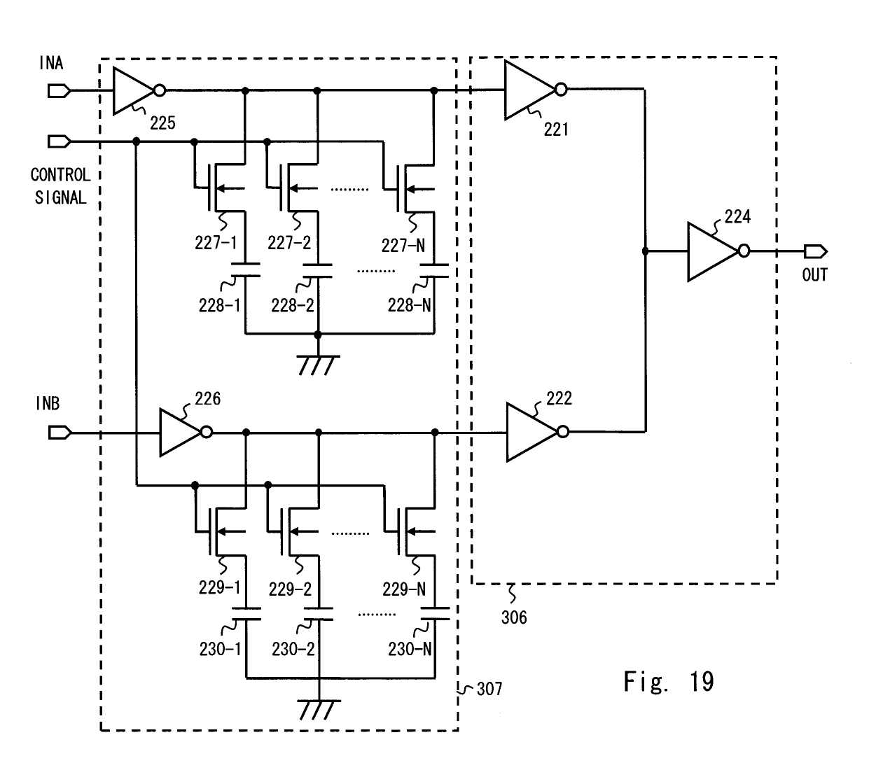

The circuit shown in FIG. 19 includes an interpolation signal adjustment circuit 307 that adjusts the inclinations of the signal changes of the clock signals that are supplied based on the first control signal, and an interpolation signal generation circuit 306 that generates the interpolation signal according to the clock signals that are adjusted. Specifically, the interpolation signal generation circuit 306 includes inverters 221, 222, and 224. The interpolation signal adjustment circuit 307 includes inverters 225 and 226, transistors 227-1 to 227-N, capacitance elements 228-1 to 228-N, transistors 229-1 to 229-N, and capacitance elements 230-1 to 230-N. The circuit shown in FIG. 19 is different from the circuit shown in FIG. 18 in that it controls the inclinations of the signal changes of the clock signals that are supplied by the load capacitance applied to the clock signals instead of controlling the inclination by the constant current sources 217 to 220.

One clock signal is input to the inverter 221 through the clock input terminal INA and the inverter 225. The other clock signal is input to the inverter 222 through the clock input terminal INB and the inverter 226. The transistors 227-1 to 227-N are provided in parallel between a node that connects the inverter 225 and the inverter 221 and a ground voltage terminal. Further, the capacitance elements 228-1 to 228-N are connected in series with the respective transistors 227-1 to 227-N. In the similar way, the transistors 229-1 to 229-N are provided in parallel between a node that connects the inverter 226 and the inverter 222 and a ground voltage terminal. Further, the capacitance elements 230-1 to 230-N are connected in series with the respective transistors 229-1 to 229-N. The interpolation signal adjustment circuit 307 controls ON/OFF of the transistors 227-1 to 227-N and 229-1 to 229-N based on the control signal. In short, the interpolation signal adjustment circuit 307 controls the load capacitance applied to the clock signals that are supplied. Accordingly, the interpolation signal adjustment circuit 307 adjusts the inclinations of the signal changes of the clock signals.

The output signal of the inverter 221 and the output signal of the inverter 222 short-circuit and are input to the inverter 224. The inverter 224 generates the interpolation signal according to the output signals of the inverters 221 and 222. Such a circuit configuration may be applied to the third exemplary embodiment as is similar to the circuit shown in FIG. 18.

Although described above is the case where the timing detection circuit 104 uses the clock signals 1 to 6 output from the PLL circuit 101, it is not limited to this example. For example, the timing detection circuit 104 may use clock signals output from another clock generation circuit.

Further, in the exemplary embodiments described above, the phase interpolation circuit 102 and the delay information generation circuit 108 use the clock signals 1 and 2. However, it is not limited to this example. The phase interpolation circuit 102 and the delay information generation circuit 108 may use clock signals other than the clock signals 1 and 2.

Furthermore, in the exemplary embodiments described above, the multi-phase clock generation circuit detects the falling edge. However, it is not limited to this example, but the multi-phase clock generation circuit may detect a rising edge. In this case, the phase interpolation circuit needs to have a circuit configuration in which the signal change of the rising of the interpolation signal is controlled.

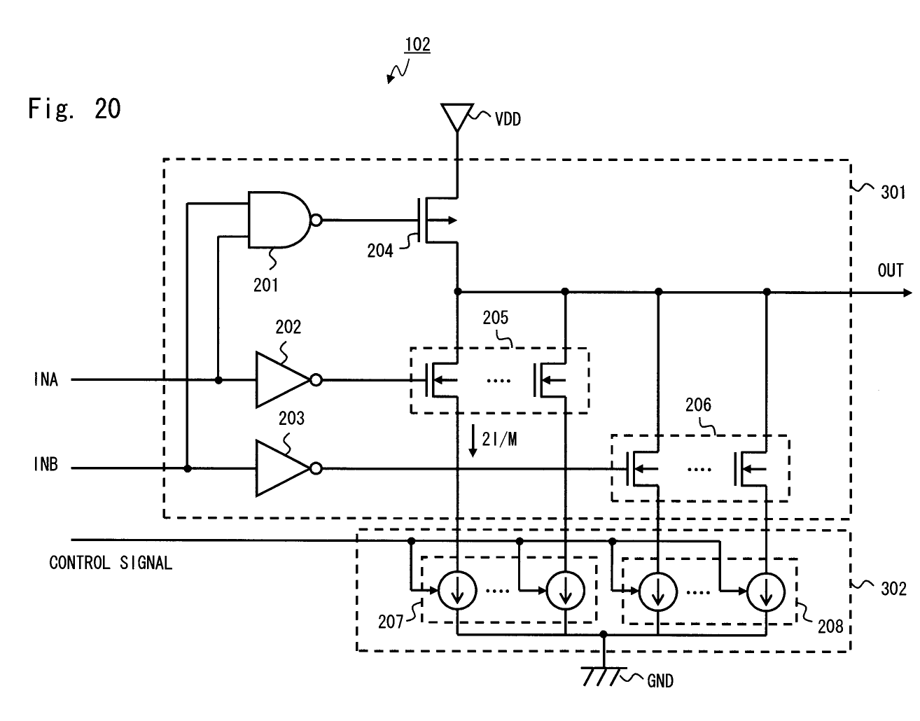

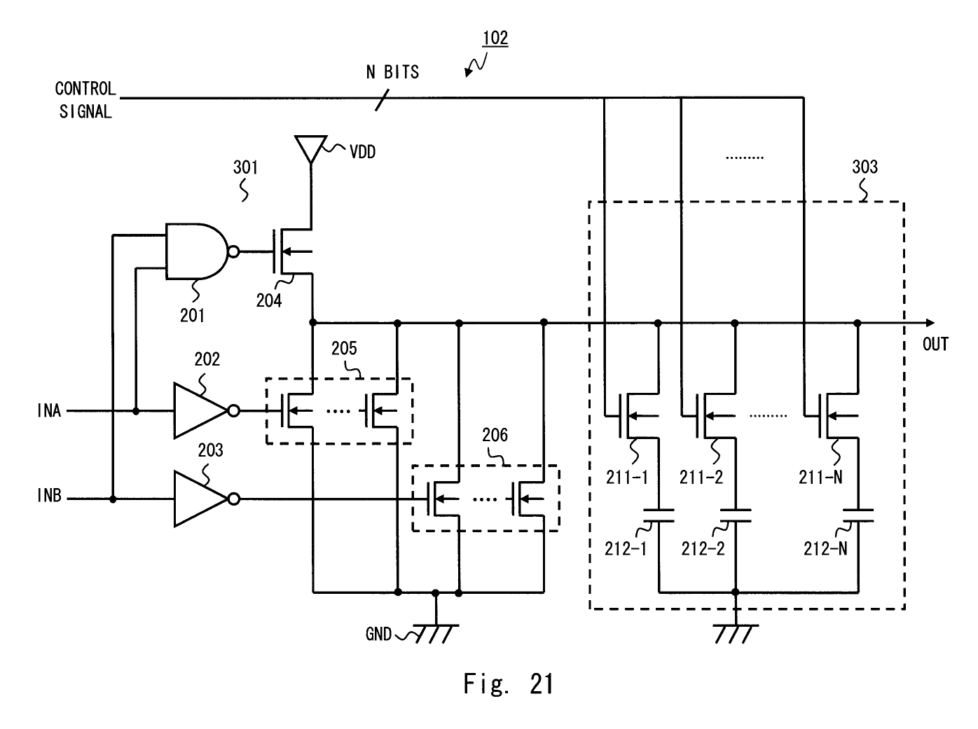

Furthermore, in the exemplary embodiments described above, the interpolation signal interpolates the phase between the output clock signals in a ratio of 1 to 1 (a case of generating the interpolation signal of 50%). However, it is not limited to this example, but the interpolation signal may interpolate the phase between the output clock signals in a different ratio. FIGS. 20 and 21 show specific examples. FIG. 20 is a modification example of the phase interpolation circuit shown in FIG. 11. FIG. 20 is different from FIG. 11 in that a current path including the transistor 205 and the constant current source 207 has M (M is a natural number)-bit width. Further, a current path including the transistor 206 and the constant current source 208 has M-bit width. More specifically, the circuit includes a transistor group 205 and a constant current source group 207. The transistor group 205 includes M transistors (switches) whose ON/OFF is controlled by the clock signal supplied to the clock input terminal INA, and the constant current source group 207 includes M constant current sources corresponding to the transistors of the transistor group 205. The phase interpolation circuit 102 further includes a transistor group 206 having M transistors (switches) whose ON/OFF is controlled by the clock signal supplied to the clock input terminal INB, and a constant current source group 208 having M constant current sources corresponding to the transistors of the transistor group 206.

The current of 2I/M flows in each of the constant current sources of the constant current source groups 207 and 208 when the corresponding switch of the constant current source is ON. Further, when both of the transistor groups 205 and 206 are ON, the current of 2I flows through the constant current source groups 207 and 208 in total. Then, the M transistors that are selected among the 2M transistors included in the transistor groups 205 and 206 are turned on at the same time. Such a circuit configuration enables to adjust the current ratio between the current that flows when only the transistor group 205 is ON and the current that flows when both of the transistor groups 205 and 206 are ON. Accordingly, the interpolation signal that is capable of interpolating the phase between the output clock signals in a desired ratio can be generated.

FIG. 21 shows a modification example of the phase interpolation circuit shown in FIG. 12. The circuit shown in FIG. 21 is different from that shown in FIG. 12 in that it includes M transistors 205 that control ON/OFF between the external output terminal OUT and the ground voltage terminal GND. Further, the circuit shown in FIG. 21 includes M transistors 206 that control ON/OFF between the external output terminal OUT and the ground voltage terminal GND. These transistors are connected in parallel between the external output terminal OUT and the ground voltage terminal GND. In this example, the M transistors 205 are called transistor group 205, and the M transistors 206 are called transistor group 206. In the circuit shown in FIG. 21, when both of the transistor groups 205 and 206 are ON, the current of 2I flows in total. Then, the M transistors selected among 2M transistors included in the transistor groups 205 and 206 are turned on at the same time. The value of the current I is controlled by the interpolation signal adjustment circuit 303 as is similar to the circuit shown in FIG. 12. Such a circuit configuration enables to adjust the current ratio between the current that flows when only the transistor group 205 is ON and the current that flows when both of the transistor groups 205 and 206 are ON. Hence, the interpolation signal that is capable of interpolating the phase between the output clock signals in a desired ratio can be generated. In FIGS. 20 and 21, the M transistors that are turned on among the 2M transistors included in the transistor groups 205 and 206 are controlled by another control signal (not shown) that is different from the first control signal. Such adjustment of the current ratio may be performed also on the circuit shown in FIG. 19.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A multi-phase clock generation circuit comprising:
a phase interpolation circuit that generates and outputs an interpolation signal based on first and second clock signals, the interpolation signal interpolating a phase between output clock signals corresponding to the first and the second clock signals; and
a control circuit that generates a first control signal to adjust a phase of the interpolation signal and outputs the first control signal to the phase interpolation circuit, wherein
the control circuit comprises:
a timing detection circuit that detects a timing of a change in a logic value of the interpolation signal; and
a control signal generation circuit that generates the first control signal according to a detection result in the timing detection circuit.

2. The multi-phase clock generation circuit according to claim 1, wherein
the control circuit generates the first control signal to decrease an inclination of a signal change of the interpolation signal if a logic value of the interpolation signal is changed between a timing of a change in a logic value of the first clock signal that is changed to one logic value and a timing of a change in a logic value of the second clock signal that is changed after the change of the first clock signal.

3. The multi-phase clock generation circuit according to claim 1, wherein
the control circuit generates the first control signal to increase an inclination of a signal change of the interpolation signal if a logic value of the interpolation signal is not changed between a timing of a change in a logic value of the second clock signal that is changed to one logic value and a timing of a change in a logic value of the first clock signal that is changed after the change of the second clock signal.

4. The multi-phase clock generation circuit according to claim 1, wherein
the control circuit further comprises a delay information generation circuit, the delay information generation circuit generating a sampling signal by delaying the first clock signal, the sampling signal having a delay amount corresponding to a delay amount applied to the first clock signal in the phase interpolation circuit, and
the timing detection circuit detects a timing of a change in a logic value of the sampling signal to detect the timing of the change in the logic value of the interpolation signal.

5. The multi-phase clock generation circuit according to claim 4, wherein
the delay information generation circuit generates the sampling signal corresponding to the interpolation signal based on the second clock signal in addition to the first clock signal.

6. The multi-phase clock generation circuit according to claim 4, wherein
the control signal generation circuit further generates a second control signal to control a delay of the sampling signal and outputs the second control signal to the delay information generation circuit.

7. The multi-phase clock generation circuit according to claim 4, wherein the delay information generation circuit has the same circuit configuration as the phase interpolation circuit.

8. The multi-phase clock generation circuit according to claim 4, wherein
the timing detection circuit comprises a plurality of flip-flops that synchronously detect the sampling signal at different timings.

9. The multi-phase clock generation circuit according to claim 1, wherein
the timing detection circuit comprises a plurality of flip-flops that synchronously detect the interpolation signal at different timings.

10. The multi-phase clock generation circuit according to claim 1, further comprising a phase locked loop circuit that generates the first and the second clock signals.

11. The multi-phase clock generation circuit according to claim 10, wherein
the timing detection circuit detects timings with a plurality of clock signals including the first and the second clock signals generated by the phase locked loop circuit.

12. The multi-phase clock generation circuit according to claim 1, wherein
the phase interpolation circuit comprises:
an interpolation signal generation circuit that generates the interpolation signal according to the first and the second clock signals; and
an interpolation signal adjustment circuit that adjusts the phase of the interpolation signal based on the first control signal.

13. The multi-phase clock generation circuit according to claim 12, wherein
the interpolation signal generation circuit comprises:
a first transistor that is provided between a first power supply and a second power supply, ON/OFF of the first transistor being controlled based on the first and the second clock signals;
a second transistor that is connected in series with the first transistor, ON/OFF of the second transistor being controlled based on the first clock signal; and
a third transistor that is connected in parallel with the second transistor, ON/OFF of the third transistor being controlled based on the second clock signal,
wherein the interpolation signal is generated from a common node of the first to the third transistors.

14. The multi-phase clock generation circuit according to claim 13, wherein
the interpolation signal adjustment circuit comprises:
a first constant current source that is connected in series with the second transistor, a current of the first constant current source being controlled based on the first control signal; and
a second constant current source that is connected in series with the third transistor, a current of the second constant current source being controlled based on the first control signal.

15. The multi-phase clock generation circuit according to claim 13, wherein
the control circuit determines current I that satisfies
0<(Cth·Vth−I·Tdiff)/2I<Tover
based on:
threshold voltage Vth of any transistor that is provided at a subsequent stage of the phase interpolation circuit;
capacitance value Cth that is loaded between the phase interpolation circuit and the any transistor;
current I that flows through each of the second and the third transistors;
phase difference Tdiff between the first and the second clock signals; and
time Tover at which the second and the third transistors are on at the same time for one cycle of the first clock signal.

16. The multi-phase clock generation circuit according to claim 13, wherein the interpolation signal adjustment circuit comprises:
a plurality of capacitance elements that are provided in parallel between the common node and the second power supply; and
a plurality of switches that are connected in series with the respective capacitance elements, ON/OFF of the plurality of switches being controlled based on the second control signal.

17. The multi-phase clock generation circuit according to claim 13, wherein
the control circuit determines capacitance value Cth that satisfies
0<(Cth·Vth−I·Tdiff)/2I<Tover
based on:
threshold voltage Vth of any transistor that is provided at a subsequent stage of the phase interpolation circuit;
capacitance value Cth that is loaded between the phase interpolation circuit and the any transistor;
current I that flows through each of the second and the third transistors;
phase difference Tdiff between the first and the second clock signals; and
time Tover at which the second and the third transistors are on at the same time for one cycle of the first clock signal.

18. The multi-phase clock generation circuit according to claim 5, wherein the delay information generation circuit has the same circuit configuration as the phase interpolation circuit, and is controlled by a predetermined fixed signal instead of the second clock signal.

19. The multi-phase clock generation circuit according to claim 18, wherein the phase interpolation circuit comprises:
an interpolation signal generation circuit that comprises a first transistor, a second transistor, and a third transistor and generates the interpolation signal from a common node of the first to third transistors, the first transistor being provided between a first power supply and a second power supply, ON/OFF of the first transistor being controlled based on the first and the second clock signals, the second transistor being connected in series with the first transistor, ON/OFF of the second transistor being controlled based on the first clock signal, the third transistor being connected in parallel with the second transistor, ON/OFF of the third transistor being controlled based on the second clock signal; and
an interpolation signal adjustment circuit that adjusts the phase of the interpolation signal based on the first control signal, wherein
when the control circuit determines one of capacitance value Cth and current I that satisfy (Cth·Vth−I·Tdiff)/2I<Tover based on:
threshold voltage Vth of any transistor that is provided at a subsequent stage of the phase interpolation circuit;
capacitance value Cth that is loaded between the phase interpolation circuit and the any transistor;
current I that flows through each of the second and the third transistors;
phase difference Tdiff between the first and the second clock signals; and
time Tover at which the second and the third transistors are on at the same time for one cycle of the first clock signal, a timing of a change in a logic value of the interpolation signal output from the phase interpolation circuit is earlier than a timing of a change in a corresponding logic value in the delay information generation circuit.

20. The multi-phase clock generation circuit according to claim 19, wherein time that corresponds time Tover is substantially twice as long as time Tover in the delay information generation circuit.
